(19) United States
(12) Patent Application Publication
(10) Pub. No.: US 2008/0266360 A1
(43) Pub. Date: Oct. 30, 2008

(54) Ink-jet head and manufacturing method thereof

(75) Inventors: Young-Seuck Yoo, Seoul (KR); Jae-Woo Joung, Suwon-si (KR); Won-Chul Sim, Seongnam-si (KR); Young-Jae Kim, Suwon-si (KR); Pil-Joong Kang, Jinju-si (KR); Chang-Sung Park, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/081,026

(22) Filed: Apr. 9, 2008

(30) Foreign Application Priority Data
Apr. 24, 2007 (KR) 10-2007-0039615

(51) Int. Cl. H01L 21/00; B41J 2/04

(52) U.S. Cl. 347/54; 438/21; 257/E21.002

(57) ABSTRACT

An ink-jet head and a method of manufacturing the ink-jet head are disclosed. The ink-jet head may include: an upper substrate, formed by processing a chamber in a silicon substrate; a middle substrate, bonded to the upper substrate and formed by processing an ink channel, which connects with the chamber, in a glass substrate; and a lower substrate, bonded to the middle substrate and formed by processing a nozzle, which connects with the ink channel, in a silicon substrate. With certain embodiments of the invention, a high level of precision may be obtained for the structures formed in the upper substrate and the lower substrate, and the middle substrate may be manufactured in low cost. Also, the substrates may be bonded together in a facilitated manner, so that production yield may be increased.

### CROSS-REFERENCE TO RELATED APPLICATIONS

This application claims the benefit of Korean Patent Application No. 10-2007-0039615 filed with the Korean Intellectual Property Office on Apr. 24, 2007, the disclosure of which is incorporated herein in its entirety by reference.

### BACKGROUND

1. Technical Field

The present invention relates to an inkjet head and manufacturing method thereof

2. Description of the Related Art

An ink-jet head is an apparatus for jetting droplets through a small nozzle by transforming electric signals to physical forces. In the ink-jet head, several structures may be formed that perform various functions. A piezoelectric element (PZT) can serve as an actuator for driving the ink-jet head, and materials such as stainless steel, ceramic and silicon can be used for the ink-jet head.

With recent developments in semiconductor technology accompanied by developments in silicon wafer processing technology, it is now possible to manufacture an ink-jet head without using separate adhesive layers, by processing each layer of the ink-jet head from a silicon wafer and bonding the layers together by SDB (silicon direct bonding).

In the case of stainless steel or ceramic, a polymer adhesive layer may be needed for bonding each layer. In the case of silicon, however, there is the advantage that an adhesive layer is not needed.

However, SDB (silicon direct bonding) may entail certain undesirable characteristics, in that the process is difficult, the yield is low, and the process requires a long period of time.

When a structure of an ink-jet head is made by processing a silicon wafer, SDB (silicon direct bonding) may generally be used. One reason for this is that, whereas structures of the head made from stainless steel or ceramic may require molds for manufacture and may pot readily allow changes in design, the structures of the head made from silicon may readily be modified by employing a photolithography method.

As shown in FIG. 1, a method according to the related art for manufacturing an ink-jet head using single crystal silicon wafers may include processing two or three wafers and bonding them together.

In order to manufacture an ink-jet head using silicon wafers, many structures may have to be formed, such as a chamber and a membrane, and a bonding process may be needed for integrating the structures. The bonding process may be performed by aligning each silicon wafer, preliminarily bonding the silicon wafers, and then applying a thermal treatment at a temperature of about 1000° C.

An ink-jet head made by such a bonding process is illustrated in FIG. 2. As such, a manufacturing method according to the related art may basically include fabricating several layers of substrates from silicon wafers and bonding them together.

In SDB (silicon direct bonding) technology, however, it is difficult to bond several layers of silicon wafers, since even a slight flaw in the surface of a wafer may lead to a generally defective bonding.

### SUMMARY

One aspect of the present invention provides an ink-jet head and a method of manufacturing the ink-jet head, which provides a high level of precision and facilitates the manufacture.

Another aspect of the present invention provides an ink-jet head that includes: an upper substrate, formed by processing a chamber in a silicon substrate; a middle substrate, bonded to the upper substrate and formed by processing an ink channel, which connects with the chamber, in a glass substrate; and a lower substrate, bonded to the middle substrate and formed by processing a nozzle, which connects with the ink channel, in a silicon substrate.

In certain embodiments, an inlet may be formed in the upper substrate, and a reservoir which connects with the inlet may be formed in the middle substrate,.

The bonding between at least one of the silicon substrates and the glass substrate may be by anodic bonding.

Yet another aspect of the present invention provides a method of manufacturing an ink-jet head, which includes: forming an upper substrate by processing a chamber in a silicon substrate; forming a middle substrate by processing an ink channel, which connects with the chamber, in a glass substrate; forming a lower substrate by processing a nozzle, which connects with the ink channel, in a silicon substrate; and bonding the upper substrate to the middle substrate and the middle substrate to the lower substrate.

The operation of forming the upper substrate may include forming an inlet in the silicon substrate, and the operation of forming the middle substrate may include forming a reservoir, which connects with the inlet, in the glass substrate.

The Bonding Performed may be Anodic Bonding

Additional aspects and advantages of the present invention will become apparent and more readily appreciated from the following description, including the appended drawings and claims, or may be learned by practice of the present invention.

### BRIEF DESCRIPTION OF THE DRAWINGS

FIG. 1 is an exploded perspective view of an ink-jet head according to the related art.

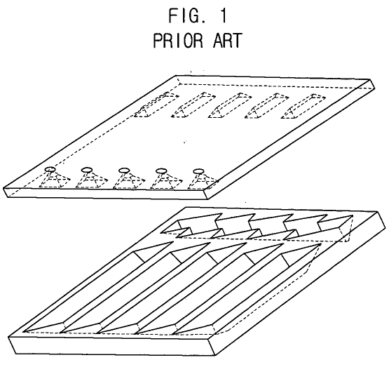

FIG. 2 is a cross-sectional view of an ink-jet head according to the related art.

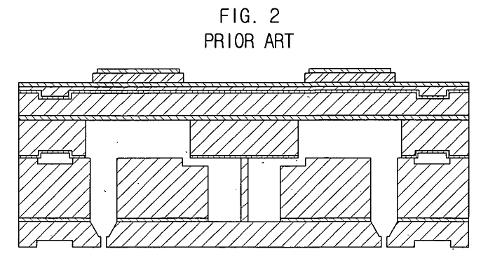

FIG. 3 is a cross-sectional view of an ink-jet head according to an embodiment of the present invention

FIG. 4 is a flowchart for a method of manufacturing an ink-jet head according to an embodiment of the present invention

### DETAILED DESCRIPTION

The ink-jet head and method of manufacturing the ink-jet head according to certain embodiments of the present invention will be described below in more detail with reference to the accompanying drawings. Those components that are the same or are in correspondence are rendered the same reference numeral regardless of the figure number, and redundant explanations are omitted.

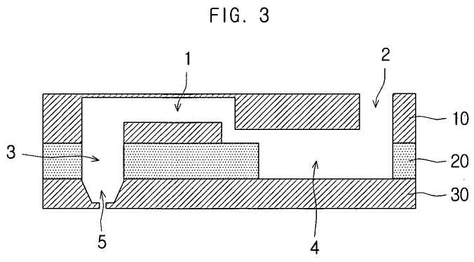

FIG. 3 is a cross-sectional view of an ink-jet head according to an embodiment of the present invention. In FIG. 3 are illustrated a chamber 1, an inlet 2, an ink channel 3, a reservoir 4, a nozzle 5, an upper substrate 10, a middle substrate 20, and a lower substrate 30.

As described above, when an ink-jet head is manufactured by fabricating several substrates from silicon wafers and bonding them together, it is not easy to achieve the bonding, since even a slight flaw can incur a general bonding failure.

This embodiment presents a method by which to form the structures that provide the basic functions of the ink-jet head, while providing greater bonding strength between substrates. That is, utilizing the fact that a silicon substrate bonds better with a glass substrate than with another silicon substrate, the upper substrate 10 and the lower substrate 30 may be fabricated from silicon substrates, while the middle substrate 20 may be fabricated from a glass substrate. In this way, the ink-jet head may include glass-silicon bonds overall.

This can be different from having an oxide layer formed over a silicon substrate. In this embodiment, the middle substrate 20 itself that is joined with silicon substrates may be fabricated by processing a glass substrate.

If a glass substrate is processed by sanding, the precision of the processing may be lowered. Thus, in this embodiment, the middle substrate 20 can be a structure that does not need high precision, such as the reservoir 4, etc., to be formed by processing a glass substrate. As a result, the substrates may readily be bonded to one another, and a high degree of precision may be maintained for the ink-jet head.

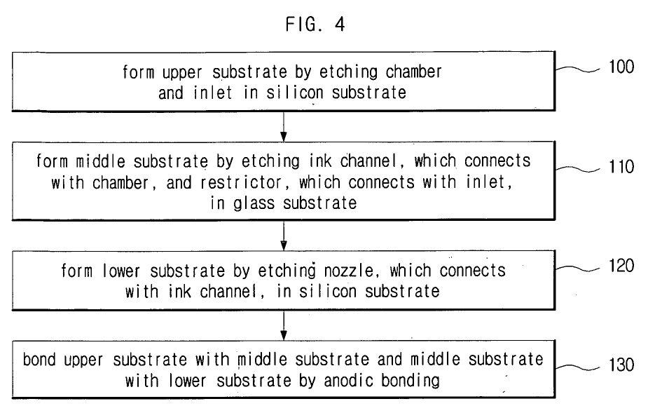

As illustrated in FIG. 4, an ink-jet head according to this embodiment may be manufactured by bonding the upper substrate 10, the middle substrate 20, and the lower substrate 30. The upper substrate 10 and the lower substrate 30 can be made from silicon substrates, while the middle substrate 20 can be made from a glass substrate.

A chamber 1 for containing and pushing an ink may be formed in the upper substrate 10, and a nozzle 5 serving as a path for jetting droplets of the ink may be formed in the lower substrate 30. In this way, structures that require high precision may be formed in the upper substrate 10 or the lower substrate 30, as the upper substrate 10 and the lower substrate 30 may be manufactured by processing silicon substrates. There are many known methods for forming the chamber 1 and the nozzle 5 by processing and etching silicon substrates. These will not be presented in detail here.

An ink channel 3 serving as a passage may be formed in the middle substrate 20, so that the ink pushed by the chamber 1 may be jetted through the nozzle 5. If an inlet 2 is formed in the upper substrate 10, ink flowing in may be contained in the reservoir 4 and supplied to the chamber 1. Since the ink channel 3 and the reservoir 4 may not affect the performance of the ink-jet head as much as the chamber 1 or the nozzle 5, the middle substrate 20 may be manufactured by processing a glass substrate, in this embodiment. There are many known methods for forming the ink channel 3 and the reservoir 4 by processing a glass substrate, examples of which include sanding methods. These will not be presented in detail here.

The bonding between the upper substrate 10 and the middle substrate 20, and between the middle substrate 20 and the lower substrate, in which the structures described above are processed, may be anodic bonding, because the bonding is between a silicon substrate and a glass substrate. Anodic bonding is a method that enables objects to be joined in a stable manner without leakage in the joints. Since anodic bonding enables substrates to be joined without an adhesive layer, a strong ink-jet head may be formed, with physical or chemical reactions prevented at the bonding interface.

FIG. 4 is a flowchart of a manufacturing method of an ink-jet head according to an embodiment of the present invention.

This embodiment presents a method for manufacturing an ink-jet head based on the embodiment described above. The method may include forming the upper substrate 10 and the lower substrate 30 by processing silicon substrates; forming the middle substrate 20 by processing a glass substrate; and joining the silicon substrates with the glass substrate by anodic bonding.

As described in the previously disclosed embodiment, a chamber 1 and an inlet 2 may be formed in the upper substrate 10 by etching, an ink channel 3 connected to the chamber 1 and a reservoir- 4 connected to the inlet 2 may be formed in the middle substrate 20 by a sanding method, and a nozzle 5 connected to the ink channel 3 may be formed in the lower substrate 30. The methods for forming the structures of the ink-jet head by processing the silicon substrates and glass substrate will not be described in further detail.

A piezoelectric element (PZT) may be joined to the structures, to complete the manufacture of the ink-jet head.

According to certain aspects of the present invention as set forth above, an ink-jet head may be manufactured by forming an upper substrate 10 and a lower substrate 30 from silicon substrates, forming a middle substrate 20 from a glass substrate, and joining the upper substrate 10, the lower substrate 30, and the middle substrate 20 by silicon-glass bonding. In this way, a high level of precision may be obtained for the structures formed in the upper substrate 10 and the lower substrate 30, and the middle substrate 20 may be manufactured in low cost. Also, the substrates may be bonded together in a facilitated manner, so that production yield may be increased.

Also, because of the anodic bonding, each substrate may be joined securely, and because of the hydrophilic property of the middle substrate, the filling of ink may be facilitated, as well as the priming operation for the initial filling of ink.

While the present invention has been described with reference to particular embodiments, it is to be appreciated that various changes and modifications may be made by those skilled in the art without departing from the spirit and scope of the present invention, as defined by the appended claims and their equivalents. As such, many embodiments other than those set forth above can be found in the appended claims.

What is claimed is:

1. An ink jet head comprising:
an upper substrate formed by processing a chamber in a silicon substrate;
a middle substrate bonded to the upper substrate and formed by processing an ink channel in a glass substrate, the ink channel connected with the chamber; and
a lower substrate bonded to the middle substrate and formed by processing a nozzle in a silicon substrate, the nozzle connected with the ink channel.

2. The ink-jet head of claim 1, wherein an inlet is formed in the upper substrate, and
a reservoir is formed in the middle substrate, the reservoir connected with the inlet.

3. The ink-jet head of claim 1, wherein at least one of the silicon substrates and the glass substrate are bonded to each other by anodic bonding.

4. A method of manufacturing an ink-jet head, the method comprising:
forming an upper substrate by processing a chamber in a silicon substrate;
forming a middle substrate by processing an ink channel in a glass substrate, the ink channel connected with the chamber;
forming a lower substrate by processing a nozzle in a silicon substrate, the nozzle connected with the ink channel; and
bonding the upper substrate to the middle substrate and the middle substrate to the lower substrate.

5. The method of claim 4, wherein the forming of the upper substrate comprises forming an inlet in the silicon substrate, and
the forming of the middle substrate comprises forming a reservoir in the glass substrate, the reservoir connected with the inlet.

6. The method of claim 4, wherein the bonding is performed by anodic bonding.
